(19) United States
(12) Patent Application Publication
(10) Pub. No.: US 2012/0119773 A1
(43) Pub. Date: May 17, 2012

(54) Testing Auxiliary Apparatus

(75) Inventors: Zhong-Yuan Yu, Taipei County (TW); Ching-Feng Hsieh, Taipei County (TW)

(73) Assignee: Askey Computer Corporation, Chung-Ho (TW)

(21) Appl. No.: 12/963,151

(22) Filed: Dec. 8, 2010

(30) Foreign Application Priority Data
Nov. 15, 2010 (TW) 99139158

(51) Int. Cl. G01R 1/067; G01R 31/00

(52) U.S. Cl. 324/756.03

(57) ABSTRACT

A testing auxiliary apparatus for assisting a testing apparatus to test signals of testing points of a circuit board, includes: a testing base having a testing platform with probes vertically disposed thereon and corresponding to the testing points, and extension testing points exposed from the testing platform and electrically connected to the probes so as for the testing apparatus to test signals; a carrier board disposed on the testing base and capable of ascending and descending relative to the testing platform and including a positioning portion for positioning the circuit board and through holes corresponding to the probes; and a pressing member disposed on the testing base for pressing the circuit board and driving the carrier board to descend such that the probes come into contact with the testing points through the through holes, thereby avoiding the inconvenience of searching for testing points on the circuit board with high-density pins.

### BACKGROUND OF THE INVENTION

1. Field of the Invention

The present invention relates to testing apparatus, and more particularly, to a testing auxiliary apparatus for capturing signals of a plurality of testing points of a circuit board under test through a plurality of probes.

2. Description of Related Art

Generally, before an electronic product such as a computer, a network device or a household appliance is mass produced or delivered, the circuit board thereof is tested to ascertain whether it functions properly, thereby ensuring a good quality of the product.

A common testing process for a circuit board involves introducing signals to a testing apparatus (such as a voltage testing apparatus, a frequency counter or an oscilloscope) so as to capture the frequency or waveform of signals of testing points on the circuit board. Therefore, testing probes are required to capture signals from selected testing points. The testing points can be component pins on the front surface of the circuit board or solder joints on the back surface of the circuit board.

However in practice, limited by surrounding components, the testing probes are not easy to be aligned with the component pins, and even a short circuit may occur to pins of a surrounding component (such as ground terminals of a capacitor) to thereby damage the surrounding component. On the other hand, in order to use solder joints as the testing points, the circuit board needs to be turned over for soldering signal connection points thereon such that the testing probes can be inserted to the signal connection points. Thereafter, the circuit board needs to be turned over again. However, during such a process, the signal connection points may be accidentally knocked off the circuit board and accordingly the soldering operation needs to be repeated.

To perform a voltage testing process to a circuit board, the circuit board is placed on a voltage testing platform, the power terminal and ground terminal of the circuit board are manually connected to the corresponding power terminal and ground terminal of the voltage testing platform, respectively, and the testing probes of the voltage testing platform are brought into contact with the testing points of the circuit board. After the testing process is completed, the testing probes are moved away from the testing points of the circuit board, the power terminal and ground terminal of the voltage testing platform are manually disconnected from the power terminal and ground terminal of the circuit board, respectively, and subsequently another circuit board is placed on the testing platform for testing.

Therefore, the above-described testing process requires soldering operations or repeated manual connecting/disconnecting operations, which is labor and time-consuming and results in a low testing efficiency. Further, if the testing points are tiny or densely distributed, the testing probes are difficult to be manually aligned and brought into contact with the testing points such that the testing probes may be in contact with wrong testing points. Even worse, the testing probes may be in contact with pins of a neighboring component so as to result in a short circuit and damage the circuit board, thereby increasing the testing cost.

### SUMMARY OF THE INVENTION

Accordingly, the present invention provides a testing auxiliary apparatus to overcome the above-described drawbacks existing in the prior art.

In order to achieve the above and other objects, the present invention provides a testing auxiliary apparatus for assisting a testing apparatus to test signals of a plurality of testing points of a circuit board under test, which comprises: a testing base comprising a testing platform, a plurality of probes vertically disposed on the testing platform and corresponding to the testing points of the circuit board under test, respectively, and a plurality of extension testing points exposed from the testing platform and electrically connected to the probes, respectively, so as for the testing apparatus to perform the signal testing process; a carrier board disposed on the testing base and capable of ascending and descending relative to the testing platform, wherein the carrier board comprises a positioning portion for positioning the circuit board under test and a plurality of through holes corresponding in position to the probes, respectively; and a pressing member disposed on the testing base for pressing the circuit board under test and driving the carrier board to descend so as to cause the probes to pass through the corresponding through holes of the carrier board and come into contact with the testing points of the circuit board under test, respectively.

In an embodiment, the testing base has a standing frame disposed at one end thereof, and the standing frame has a driving unit disposed thereon for controlling the movement of the pressing member, wherein the driving unit comprises: a fastening member fastened to the standing frame and having a first coupling end and a first fastening end opposite to the first coupling end and having a tubular portion; a handle having a bending portion, a pivot end, and a holding portion extending from the two ends of the bending portion, respectively, wherein the pivot end is pivotally connected to the first coupling end of the fastening member; an operating rod having a second coupling end penetrating through the tubular portion and a second fastening end opposite to the second coupling end and fastened to an end surface of the pressing member; and a link member having one end pivotally connected to the bending portion of the handle and the other end pivotally connected to the second coupling end of the operating rod penetrating through the tubular portion.

According to the present invention, since the extension testing points are disposed on the testing platform and electrically connected to the probes on the testing platform, the tester only needs to bring a probe head of the testing apparatus into contact with the extension testing points for signal testing of the circuit board, thereby avoiding the inconvenience of searching for tiny testing points on the circuit board with high-density pins so as to effectively avoid wrong contacts and short circuits, save the testing time and improve the testing efficiency.

### BRIEF DESCRIPTION OF DRAWINGS

FIG. 1 is a perspective view of a testing auxiliary apparatus of the present invention;

FIG. 2A is a cross-sectional view illustrating the positional relationship between the carrier board, pressing member and testing platform of the testing auxiliary apparatus of the present invention; and

FIG. 2B is a cross-sectional view of the testing auxiliary apparatus with a circuit board under test disposed on the carrier board and pressed by the pressing member.

### DETAILED DESCRIPTION OF PREFERRED EMBODIMENTS

The following embodiments are provided to illustrate the present invention. Those skilled in the art will readily understand other advantages and functions of the present invention in accordance with the contents disclosed in this specification. The present invention can also be performed or applied by other different embodiments. Various modifications and variations based on different viewpoints and applications can be made in the details of the specification without departing from the spirit of the present invention.

It should be noted that the drawings are simplified schematic diagrams and only show components relating to the present invention. In practice, the layout of the components may be far more intricate.

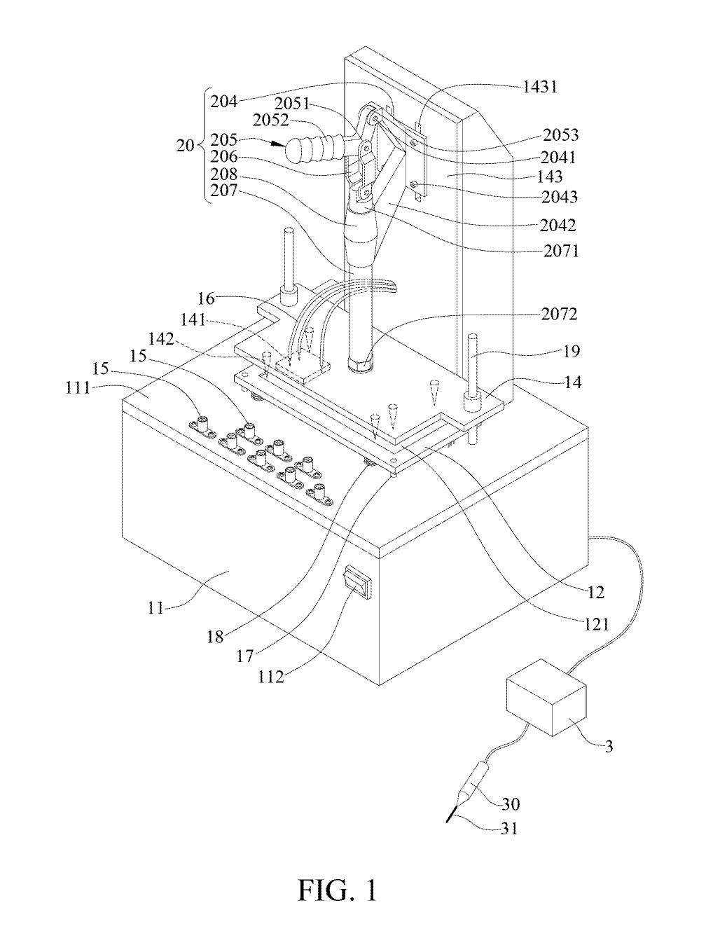

FIG. 1 is a perspective view of a testing auxiliary apparatus according to the present invention. Referring to the drawing, the testing auxiliary apparatus is used for assisting a testing apparatus 3 to capture and test voltage or frequency signals of a plurality of testing points of a circuit board under test (not shown).

The testing auxiliary apparatus at least comprises: a testing base 11, and a carrier board 12 and a pressing member 14 disposed on the testing base 11.

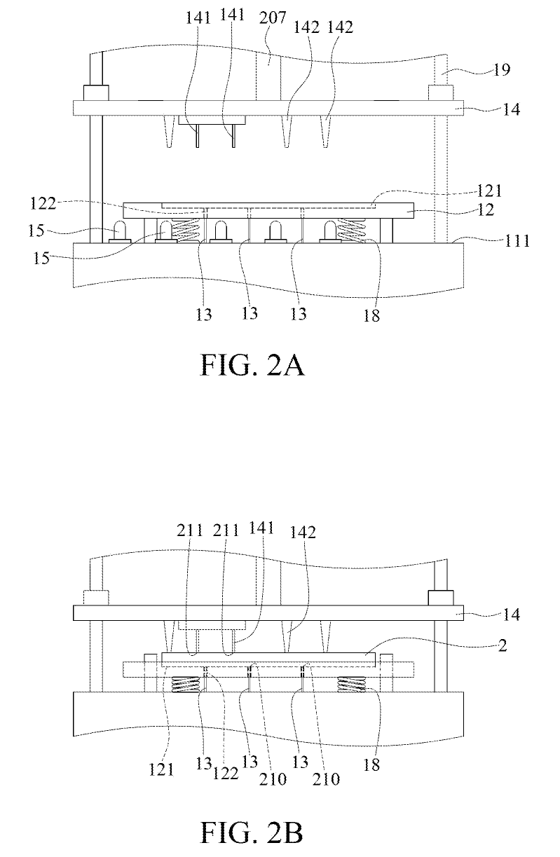

Therein, the testing base 11 comprises a testing platform 111 disposed on a surface thereof, and a plurality of probes (probes 13 shown in FIG. 2A) vertically disposed on the testing platform 111 and corresponding to testing points of the circuit board under test, respectively. A plurality of return springs 18 is connected to the testing platform 111, and a plurality of sliding members 17, 19 for the carrier board 12 and the pressing member 14, respectively, are vertically disposed on the testing platform 111.

The carrier board 12 is used for carrying the circuit board under test. The carrier board 12 comprises a plurality of through holes corresponding in position to the probes on the testing platform 111, respectively, and a positioning portion for positioning the circuit board under test. In the present embodiment, the positioning portion is a recess 121 for receiving and positioning the circuit board under test, and the through holes are disposed in the recess 121. In practice, the positioning portion is not limited to the recess. For example, the positioning portion can comprise a region for receiving the circuit board under test and a fixing member disposed around the region so as to allow the circuit board under test to be disposed in the region and fixed by the fixing member. The carrier board 12 is capable of ascending and descending relative to the testing platform 111 through the sliding members 17, and can be supported by the return springs 18 over the testing platform 111. The return springs 18 can provide return forces to the carrier board 12.

The pressing member 14 is capable of ascending and descending relative to the testing platform 111 through the sliding members 19. The pressing member 14 comprises a plurality of pins 142 disposed on a surface facing the carrier board 12 such that when the pressing member 14 is pressed down towards the circuit board under test on the carrier board 12, the pins 142 can stably secure the circuit board under test on the carrier board 12.

The testing base 11 further comprises a standing frame 143 with a driving unit 20 fastened thereon. The driving unit 20 comprises a fastening member 204, a handle 205, an operating rod 207 and a link member 206. Therein, the fastening member 204 is fastened to the standing frame 143 and comprises a first coupling end 2041 and a first fastening end 2042 opposite to the first coupling end 2041 and having a tubular portion 208. The handle 205 comprises a bending portion 2051, and a pivot end 2053 and a holding portion 2052 extending from the two ends of the bending portion 2051, respectively, wherein the pivot end 2053 is pivotally connected to the first coupling end 2041 of the fastening member 204. The operating rod 207 has a second coupling end 2071 penetrating through the tubular portion 208 and a second fastening end 2072 opposite to the second coupling end 2071 and fastened to an end surface of the pressing member 14, wherein the second coupling end 2071 faces the handle 205 and can freely move through the tubular portion 208. The link member 206 has one end pivotally connected to the bending portion 2051 of the handle 205 and the other end pivotally connected to the second coupling end 2071 of the operating rod 207 penetrating through the tubular portion 208. The handle 205 substantially has a V-shape and the holding portion 2052 of the handle 205 is provided for the tester to hold so as to control the pressing member 14 to ascend or descend relative to the testing platform 111.

The standing frame 143 further comprises a position-limiting slot 1431, and the fastening member 204 is fastened in the position-limiting slot 1431 through a plurality of screws 2043. Since the position-limiting slot 1431 longitudinally extends along the standing frame 143, the fastening member 204 can be selectively fastened to the standing frame 143 at a different height position through the position-limiting slot 1431.

To perform a testing process to the circuit board under test, the handle 205 is pulled towards the testing platform 111 to cause the link member 206 to move towards the testing platform 111 along with the bending portion 2051 of the handle 205, thereby guiding the operating rod 207 to move towards the testing platform 111. As such, the pressing member 14 is moved close to the testing platform 111 so as to press against the carrier board 12, thereby compressing the return springs 18 and causing the probes on the testing platform 111 to pass through the through holes of the carrier board 12 so as to come into contact with the testing points of the circuit board under test, respectively.

On the other hand, when the handle 205 is moved away from the testing platform 111, the link member 206 is also moved away from the testing platform 111 along with the bending portion 2051 of the handle 205 so as to guide the operating rod 207 to move towards the handle 205, thereby causing the pressing member 14 to move away from the testing platform 111. As such, the carrier board 12 is moved upwards by the return forces of the return springs 18, thus separating the testing points of the circuit board under test from the corresponding probes.

Further, the testing base 11 can have a receiving space (not shown) disposed therein for receiving a plurality of signal connection lines (not shown). The signal connection lines have one ends connected to the probes on the testing platform 111, respectively and the other ends connected to extension testing points 15 on the testing platform 111, respectively. Further, according to the specification or testing requirement of the circuit board under test, a plurality of probes 141 (pressing probes) can be selectively disposed on a surface of the pressing member 14 facing the carrier board 12. Each of the probes 141 is connected to one end of a signal connection line 16, and the other end of the signal connection line 16 is connected to one of the extension testing points 15 on the testing platform 111. Therefore, to perform a testing process to the circuit board under test, the tester only needs to bring the head 31 of a probe 30 of the testing apparatus 3 into contact with the extension testing points 15, thereby eliminating the need to bring the probe head into contact with tiny or densely distributed testing points of the circuit board under test that otherwise may cause the probe head to come into contact with wrong testing points and even result in short circuit. Further, the testing process is facilitated by avoiding the conventional manual soldering operations or connecting/disconnecting operations.

FIGS. 2A and 2B illustrate the operation relationship between the carrier board, the pressing member and the testing platform, wherein FIG. 2A is a cross-sectional view illustrating the positional relationship between the carrier board, the pressing member and the testing platform, and FIG. 2B is a cross-sectional view of the testing auxiliary apparatus with the circuit board under test disposed on the carrier board and pressed by the pressing member. Referring to FIGS. 2A and 2B, when pressed by the operating rod 207 of the driving unit 20, the pressing member 14 descends relative to testing platform 111 along with the carrier board 12. Since the through holes 122 of the carrier board 12 correspond to the probes 13, respectively, when the operating rod 207 is moved through operation of the handle 205 so as to cause the pressing member 14 to move towards the testing platform 111, press against the carrier board 12 and further cause the carrier board to move towards the testing platform 111, the probes 13 pass through the through holes 122 and protrude from the recess 121 so as to come into contact with the testing points 210 on the lower surface of circuit board 2, respectively, as shown in FIG. 2B. Further, the probes 141 of the pressing member 14 can come into contact with testing points 211 on the upper surface of the circuit board 2. Furthermore, the probes 13, 141 can function as power terminals or ground terminals of the circuit board for a power supply circuit. For example, in FIG. 2B, the probes 141 of the pressing member 14 function as power terminals or ground terminals of the circuit board 2 for power supply, and the probes 13 on the carrier board 12 function as signal testing terminals of the testing points 211 of the circuit board 2. In addition, as shown in FIG. 1, the testing base 11 can further comprise a power switch 112 for switching on or switching off the above-described power supply circuit.

According to the present invention, the circuit board under test is disposed on the carrier board and secured by the pressing member, and the plurality of through holes of the carrier board allows the probes of the testing platform to protrude therefrom so as to come into contact with the corresponding testing points of the circuit board under test. Further, the pressing member can have probes disposed thereon. As such, the front surface and back surface of the circuit board can be tested at one time. In addition, since the extension testing points are disposed on the testing platform and electrically connected to the probes on the testing platform, the tester only needs to bring the head 31 of the probe 30 of the testing apparatus 3 into contact with the extension testing points 15 instead of searching for tiny testing points on the circuit board with high-density pins, thereby effectively avoiding wrong contacts and short circuits and facilitating the testing process.

The above-described descriptions of the detailed embodiments are intended to illustrate the preferred implementation according to the present invention but are not intended to limit the scope of the present invention. Accordingly, all modifications and variations completed by those with ordinary skill in the art should fall within the scope of present invention defined by the appended claims.

What is claimed is:

1. A testing auxiliary apparatus for assisting a testing apparatus to test signals of a plurality of testing points of a circuit board under test, comprising:
a testing base comprising a testing platform, a plurality of probes vertically disposed on the testing platform and corresponding to the testing points of the circuit board under test, respectively, and a plurality of extension testing points exposed from the testing platform and electrically connected to the probes, respectively, so as for the testing apparatus to perform the signal testing process;
a carrier board disposed on the testing base and capable of ascending and descending relative to the testing platform, wherein the carrier board comprises a positioning portion for positioning the circuit board under test and a plurality of through holes corresponding in position to the probes, respectively; and
a pressing member disposed on the testing base for pressing the circuit board under test and driving the carrier board to descend so as to cause the probes to pass through the corresponding through holes of the carrier board and come into contact with the testing points of the circuit board under test, respectively.

2. The apparatus of claim 1, further comprising a plurality of sliding members vertically disposed on the testing platform and penetrating through the carrier board for allowing the carrier board to ascend and descend relative to the testing platform.

3. The apparatus of claim 1, wherein the carrier board further has a plurality of return springs connected to the testing base for supporting the carrier board over the testing platform and providing return forces to the carrier board.

4. The apparatus of claim 1, wherein the pressing member has a plurality of pins disposed on a surface facing the carrier board such that when the pressing member is pressed down towards the circuit board under test on the carrier board, the pins secure the circuit board under test on the carrier board.

5. The apparatus of claim 1, wherein the testing base has a standing frame disposed at one end thereof, and the standing frame has a driving unit disposed thereon for controlling movement of the pressing member, wherein the driving unit comprises:
a fastening member fastened to the standing frame and having a first coupling end and a first fastening end opposite to the first coupling end and having a tubular portion;
a handle having a bending portion, a pivot end, and a holding portion extending from two ends of the bending portion, respectively, wherein the pivot end is pivotally connected to the first coupling end of the fastening member;
an operating rod having a second coupling end penetrating through the tubular portion and a second fastening end opposite to the second coupling end and fastened to an end surface of the pressing member; and
a link member having one end pivotally connected to the bending portion of the handle and the other end pivotally connected to the second coupling end of the operating rod penetrating through the tubular portion.

6. The apparatus of claim 1, wherein the pressing member has a plurality of pressing probes disposed on a surface facing the carrier board, the pressing probes being adapted to electrically contact the circuit board under test when the circuit board under test is pressed by the pressing member.

7. The apparatus of claim 6, wherein the pressing probes function as power terminals or ground terminals of the circuit board under test for a power supply circuit.

8. The apparatus of claim 1, wherein the plurality of probes function as power terminals or ground terminals of the circuit board under test for a power supply circuit.

9. The apparatus of claim 8, wherein the testing base further has a control switch for switching on or switching off the power supply circuit.

10. The apparatus of claim 1, wherein the positioning portion of the carrier board is a recess and the through holes of the carrier board are disposed in the recess.
